(19) United States
(12) Patent Application Publication
(10) Pub. No.: US 2006/0289051 A1
(43) Pub. Date: Dec. 28, 2006

(54) Thermoelectric converter for a heat transfer device

(75) Inventors: Yasuhiko Niimi, Handa-city (JP); Yuji Ito, Okazaki-city (JP); Isao Kuroyanagi, Anjo-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/473,406

(22) Filed: Jun. 22, 2006

(30) Foreign Application Priority Data
Jun. 24, 2005 (JP) 2005-185487
Dec. 22, 2005 (JP) 2005-370103

(51) Int. Cl. H01L 35/28

(52) U.S. Cl. 136/203

(57) ABSTRACT

A thermoelectric converter is disclosed which includes a body and an extension member. The body includes a plurality of dissimilar thermoelectric elements in an array. The body also includes a first substrate with a first electrically conductive pattern portion that is electrically connected to the plurality of dissimilar thermoelectric elements. Also, the body includes a second substrate with a second electrically conductive pattern portion that is electrically connected to the plurality of dissimilar thermoelectric elements. The extension member includes an extension pattern portion that is electrically connected to at least one of the first and second electrically conductive pattern portions. The extension member extends away from the body.

### CROSS REFERENCE TO RELATED APPLICATIONS

The following is based on and claims priority to Japanese Patent Application No. 2005-185487, filed Jun. 24, 2005, and Japanese Patent Application No. 2005-370103, filed Dec. 22, 2005, the disclosures of which are incorporated herein by reference.

### FIELD

The present invention relates to a thermoelectric converter and, more particularly, to a thermoelectric converter for a heat transfer device.

### BACKGROUND

Theremoelectric devices have been proposed, which rely on the Peltier effect (see, e.g., Japanese Patent No. 2002-208741). In one example, a thermoelectric converter has P-type thermoelectric elements and N-type thermoelectric elements alternately and adjacently fitted to plural opening portions formed in an insulating plate. The device also has an electrode section for sequentially connecting the P-type thermoelectric elements and the N-type thermoelectric elements so as to sequentially supply an electric current to the adjacent P-type thermoelectric elements and N-type thermoelectric elements. The electrode section is an electrode film formed on a flexible electronic circuit substrate, which is a resin film.

To supply electric power to the thermoelectric element, a lead wire, etc. is soldered onto the electronic circuit substrate on a forming side of the electrode film. The soldering may add undesirable cost and time to the manufacturing process. Also, the connection strength of the lead wire, etc. may be inadequate, and the thermoelectric element may malfunction as a result.

### SUMMARY OF THE INVENTION

A thermoelectric converter is disclosed which includes a body and an extension member. The body includes a plurality of dissimilar thermoelectric elements in an array. The body also includes a first substrate with a first electrically conductive pattern portion that is electrically connected to the plurality of dissimilar thermoelectric elements. Also, the body includes a second substrate with a second electrically conductive pattern portion that is electrically connected to the plurality of dissimilar thermoelectric elements. The extension member includes an extension pattern portion that is electrically connected to at least one of the first and second electrically conductive pattern portions. The extension member extends away from the body.

A thermoelectric converter is also disclosed, which includes a body and an extension member. The body includes a plurality of dissimilar thermoelectric elements in an array. Further, the body includes a first substrate with a first electrically conductive pattern portion. The first substrate is disposed on a first side of the array, and the first electrically conductive pattern portion is electrically connected to the plurality of dissimilar thermoelectric elements. Also, the first electrically conductive pattern portion includes a first electrode portion. The body also includes a second substrate with a second electrically conductive pattern portion. The second substrate is disposed on a second side of the array, and the second electrically conductive pattern portion is electrically connected to the plurality of dissimilar thermoelectric elements. Moreover, the second electrically conductive pattern portion includes a second electrode portion. The body further includes at least one cooling electrode member thermally coupled to the first electrode portion for heat transfer therewith. Additionally, the body includes at least one heating electrode member thermally coupled to the second electrode portion for heat transfer therewith. The extension member includes an extension member with an extension pattern portion that is electrically connected to at least one of the first and second electrically conductive pattern portions. The extension member extends away from the body.

A heat transfer device for a duct through which a heat transfer medium flows is additionally disclosed. The heat transfer device includes a body and an extension member. The body includes a plurality of dissimilar thermoelectric elements in an array. The body also includes a first substrate with a first electrically conductive pattern portion that is electrically connected to the plurality of dissimilar thermoelectric elements. Moreover, the body includes a second substrate with a second electrically conductive pattern portion that is electrically connected to the plurality of dissimilar thermoelectric elements. The extension member includes an extension pattern portion that is electrically connected to at least one of the first and second electrically conductive pattern portions. The extension member extends away from the body so as to partition the duct into a cooling portion, in which the heat transfer medium is cooled, and a heating duct, in which the heat transfer medium is heated.

### BRIEF DESCRIPTION OF THE DRAWINGS

FIGS. 1A-1C show one embodiment of a thermoelectric converter, where FIG. 1A is a top view of the thermoelectric converter, FIG. 1B is a sectional view taken along the line IB-IB of FIG. 1C, and FIG. 1C is a bottom view of the thermoelectric converter;

FIGS. 2A-2E are sectional views of an electrode substrate showing a manufacturing method thereof;

FIGS. 3A and 3B are sectional views showing another embodiment of the electrode substrate;

FIG. 4 is a sectional view showing the thermoelectric converter of FIGS. 1A-1C assembled in a cooling-heating device;

FIG. 5 is a sectional view taken along the line V-V of FIG. 4;

FIG. 6 is a sectional view showing one embodiment of a connector for the thermoelectric converter;

FIG. 7 is a sectional view of an assembly portion showing another embodiment of an assembly structure of case members for the thermoelectric converter;

FIGS. 8A and 8B show another embodiment of the thermoelectric converter, where Fig. BA is a bottom view of the thermoelectric converter, and FIG. 8B is a sectional view taken along line VIIIB-VIIIB of Fig. BA;

FIG. 9 is a sectional view of another embodiment of the thermoelectric converter;

FIGS. 10A-10D are sectional views showing additional embodiments of the thermoelectric converter; and

FIGS. 11A-11D are sectional views showing additional embodiments of the thermoelectric converter.

### DETAILED DESCRIPTION OF THE EMBODIMENTS

(First embodiment)

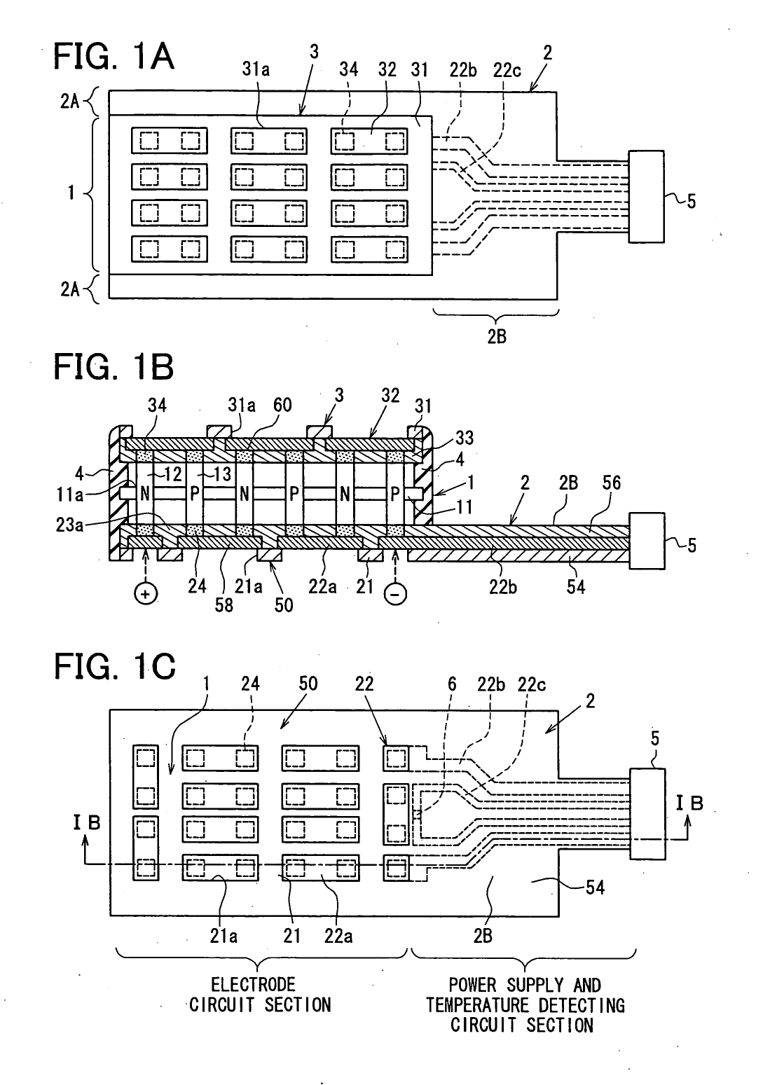

Referring initially to FIGS. 1A-1C, one embodiment of a thermoelectric converter is shown. The thermoelectric converter generally includes a thermoelectric element assembly body 1, and an extension member 2.

The thermoelectric element assembly body 1 includes a plurality of dissimilar thermoelectric elements 12, 13 arranged in an array. In one embodiment, the thermoelectric elements 12, 13 are P-type thermoelectric elements 13 and N-type thermoelectric elements 12. In the embodiment shown, the array includes four rows and six columns of thermoelectric elements 12, 13. The thermoelectric elements 12, 13 are alternately positioned.

Also, the thermoelectric elements 12, 13 extend through corresponding apertures 11a of a holding member 11. In the embodiment shown, the holding member 11 is flat and plate shaped. The holding member 11 is made of an insulating material such as glass epoxy, PPS resin, LCP resin or PET resin, etc.

The thermoelectric converter can include any suitable number of thermoelectric elements 12, 13, and the array pattern can be of any suitable type without departing from the scope of the present disclosure. The number of thermoelectric elements 12, 13 and the array pattern can be selected such that the thermoelectric converter exhibits a desired heat transfer performance.

In one embodiment, the P-type thermoelectric element 13 is a semiconductor part constructed by a P-type semiconductor made of a bismuth-tellurium (Bi—Te) system compound. Also, the N-type thermoelectric element 12 is similarly a semiconductor part constructed by an N-type semiconductor made of the bismuth-tellurium system compound. It will be appreciated that other materials could be used for the P-type and N-type thermoelectric elements 12, 13, such as an iron-silicon system compound semiconductor, a cobalt-antimony system compound semiconductor, etc. Both the P-type and N-type elements 12, 13 are molded in the hold plate 11 such that the elements 12, 13 alternate one-by-one in each row and each column.

Furthermore, the body 1 includes a first substrate 50 and a second substrate 3. The first substrate 50 is disposed on one side of the array of thermoelectric elements 12, 13, and the second substrate 3 is disposed on the opposite side of the array of thermoelectric elements 12, 13. In other words, the array is disposed between the first and second substrates 50, 3.

In the embodiment shown, the first substrate 50 includes a plurality of layers. More specifically, the first substrate 50 includes a first insulating base material 21, an insulating film 23a, and a first electrically conductive pattern portion 22a interposed between the first insulating base material 21 and the insulating film 23a. Likewise, the second substrate 3 includes a plurality of layers. In the embodiment shown, the second substrate 3 is a three-layer structure of a second insulating base material 31, a second electrically conductive pattern portion 32, and an insulating film 33. The second electrically conductive pattern portion 32 is interposed between the insulating base material 31 and the insulating film 33.

The first and the second electrically conductive pattern portions 22a, 32 are each electrically connected to the thermoelectric elements 12, 13. As such, the thermoelectric elements 12, 13 are electrically connected to each other. In one embodiment, the first and second electrically conductive pattern portions 22a, 32 are made of copper film, and the pattern of each is made using an etching technique. As will be explained, when power is supplied, a heat gradient (i.e., a heat difference) is developed.

The extension member 2 is planar and is coupled at one end to the body 1 and extends away from the body 1. In the embodiment shown, for example, the extension member 2 includes a first portion 2B and a plurality of second portions 2A. The first portion 2B extends longitudinally away from the body 1, and the second portions 2A extend transversely away from opposite sides of the body 1.

The extension member 2 includes a plurality of layers. For instance, the first portion 2B of the extension member 2 includes a first insulating base material 54, an insulating film 56, a power supply extension pattern portion 22b, and a sensor signal extension pattern portion 22c. The extension pattern portions 22b, 22c are interposed between the first insulating base material 54 and the insulating film 56.

As shown in FIGS. 1B and 1C, the first insulating base material 54 is integrally connected to the first insulating base material 21 of the first substrate 50. Also, the insulating film 56 is integrally connected to the insulating film 23a of the first substrate 50. Furthermore, the power supply extension pattern portion 22b is integrally and electrically connected to the first electrically conductive pattern portion 22a,and as such, the power supply extension pattern portion 22b supplies power to the thermoconductive elements 12, 13.

More specifically, in the embodiment shown, respective layers of the first substrate 50 and the first portion 2B are integrally connected and are co-planar. As such, the thermoelectric converter can be manufactured more easily, and malfunctions are less likely. For instance, the power supply extension pattern portion 22b and the first electrically conductive pattern portion 22a can be formed in a continuous pattern shape for simpler manufacturing and for improved reliability of the power supply to the thermoelectric elements 12, 13.

In one embodiment, the layers of the first substrate 50, the second substrate 3, and the extension member 2 are made by etching. In another embodiment, at least one of the first substrate 50, the second substrate 3, and the extension member 2 is made with a flexible print substrate, a flat cable covered by resin film, and/or a ribbon electric wire with wire individually insulated and coated.

In one embodiment, a strong, flexible resin film that is thermally and electrically insulating (e.g., a resin film of a polyimide or aramid) is used for making at least one of the first insulating base material 21, the second insultating base material 31, and the insulating films 23, 33.

The power supply extension pattern portion 22b supplies electric power to the thermoelectric elements 12, 13 from a direct current electric power source (not shown) through a connector 5. The sensor signal extension pattern portion 22c transmits signals to and from a temperature sensor element 6 (e.g., thermistor). The temperature sensor element 6 is a chip element and is soldered and connected onto the sensor signal extension pattern portion 22c.

The temperature sensor element 6 is disposed adjacent the body 1 (i.e., on the downstream side of the body 1). During operation, a temperature gradient develops in a heat transfer medium (i.e., a fluid) flowing downstream (i.e., away from the body 1 and toward the extension member 2). The temperature sensor element 6 detects the temperature for electric conduction control, etc. of the thermoelectric converter.

The thermoelectric elements 12, 13 are connected in series, and the connection is sequentially made from a positive side terminal of the power source to a negative side terminal of the power source. (Polarities (+) and (−) shown within FIG. 1B are provided to show a local polarity relation.) In this embodiment, all the thermoelectric elements 12, 13 are arrayed and connected in series. One end of each thermoelectric element 12, 13 is connected to the positive side terminal of the power source, and the other end is connected to the negative side terminal of the power source.

In the insulating film 23a, openings are arranged according to the locations of the thermoelectric elements 12, 13 so that the thermoelectric elements 12, 13 can be electrically connected to the first electrically conductive pattern portion 22a. (The thermoelectric elements 12, 13 are electrically connected to electrodes of the first electrically conductive pattern portion 22a). In one embodiment, a plurality of solder joining portions 24 are formed in corresponding openings in order to electrically connect the thermoelectric elements 12, 13 to the first electrically conductive pattern portion 22a. Likewise, in the insulating film 33, openings are arranged according to the locations of the thermoelectric elements 12, 13 so that the thermoelectric elements 12, 13 can be electrically connected to the second electrically conductive pattern portion 32. (The thermoelectric elements 12, 13 are electrically connected to electrodes of the second electrically conductive pattern portion 32). In one embodiment, a plurality of solder joining portions 34 are formed in corresponding openings in order to electrically connect the thermoelectric elements 12, 13 to the second electrically conductive pattern portion 32.

Furthermore, the first insulating base material 21 includes a plurality of openings 21 a to thereby expose the first electrically conductive pattern portion 22a (i.e., to expose electrodes of the first electrically conductive pattern portion 22a). Likewise, the second insulating base material 31 includes a plurality of openings 31a to thereby expose the second electrically conductive pattern portion 32 (i.e., to expose electrodes of the second electrically conductive pattern portion 32).

Moreover, a sealant 4 of an annular shape (e.g., a rectangular shape) is disposed about the peripheries of the first and second substrates 50, 3. As such, the thermoelectric elements 12, 13 are encapsulated by the sealant 4, the first substrate 50, and the second substrate 3 so as to reduce exposure to moisture and other foreign matter. The sealant 4 can be of any suitable type, such as rubber or resin.

In the embodiment shown, heating occurs on the side of the first substrate 50 (i.e., heat is radiated), and cooling occurs on the side of the second substrate 3 (i.e., heat is absorbed). However, if the polarity of the direct current is reversed, cooling occurs on the side of the first substrate 50, and heating occurs on the side of the second substrate 3.

(Manufacturing method)

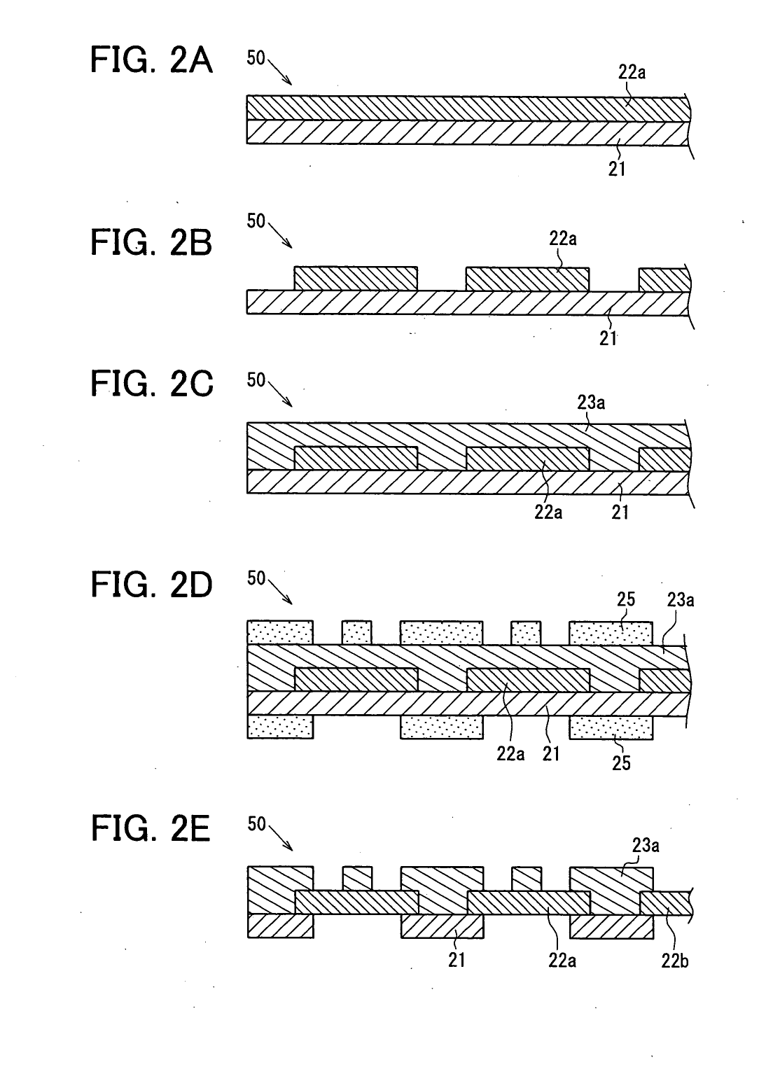

Next, FIGS. 2A to 2E show one example of a manufacturing method of the first electrode substrate 50. It will be appreciated that the formation of the first electrode substrate 50 can be used to simultaneously form the extension member 2 because the extension member 2 is integrally connected in the embodiment of FIGS. 1A-1C. It will also be appreciated that the second substrate 3 can be formed in a similar, but separate, manufacturing process.

A resin base material that is a thermal and electrical insulator and that is flexible and pliable (e.g., polyimide, aramid, etc.) is used as the first insulating base material 21. As such, the base material 21 reduces thermal stress, etc. applied thereto. In another embodiment, the base material 21 is rigid. An electrically conductive thin film (e.g., copper thin film, aluminum thin film, etc.) is used to form the first electrically conductive portion 22a.

As shown in FIG. 2A, the electrically conductive film for the conductive portion 22a is adhered to the resin film 21. In another embodiment, copper plating is performed by sputtering.

Then, in a process shown in FIG. 2B, patterning is performed in a predetermined electrode pattern shape by etching processing using a photo-resist film (not shown). As such, the first electrically conductive pattern portion 22a is defined. In the embodiment of FIGS. 1A-1C, the first pattern portion 22a,the power supply extension pattern portion 22b, and the sensor signal extension pattern portion 22c are simultaneously formed in the step illustrated in FIG. 2B.

Next, as shown in FIG. 2C, the insulating film 23a is adhesively formed on the base material 21 the first electrically conductive pattern portion 22. In one embodiment, the insulating film 23a is made of the same material as the base material 21. Subsequently, in processes shown in FIGS. 2D and 2E, a resist film 25 is arranged on the insulating film 23a in a predetermined pattern. Then, the first electrically conductive pattern portion 22a is exposed using a chemical or mechanical etching technique or a sand blast processing technique). Thereafter, the resist film 25 is removed.

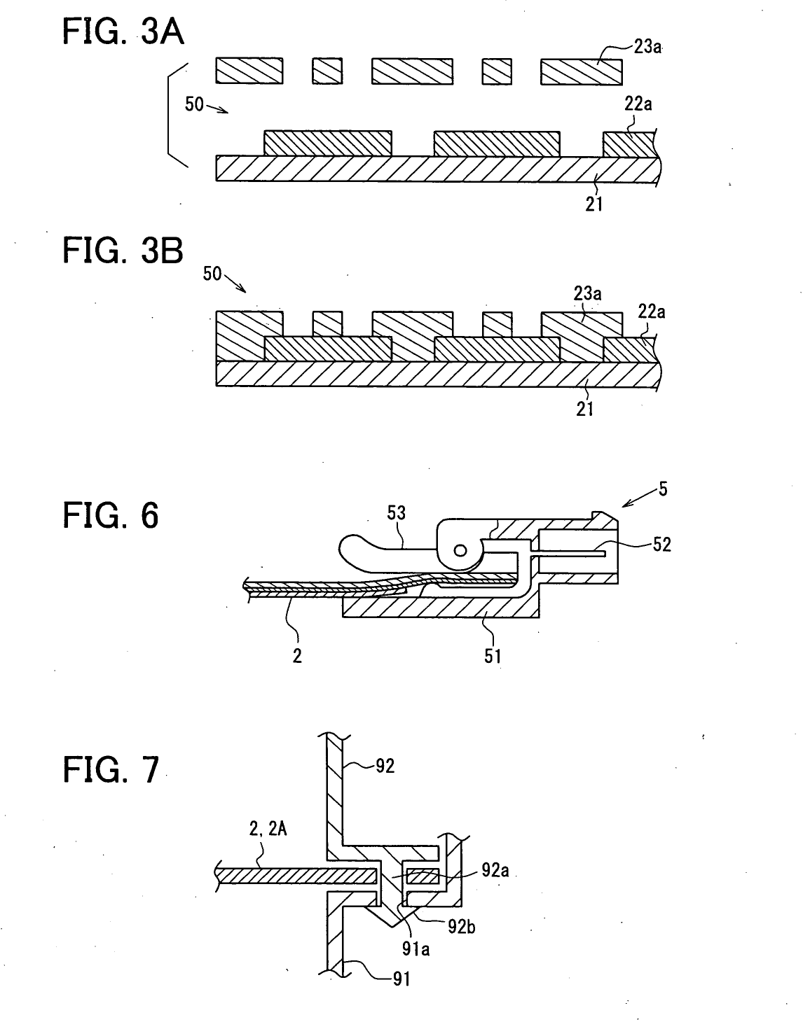

Another embodiment of the manufacturing method is shown in FIGS. 3A and 3B. The first substrate 50 is manufactured by separately preparing the insulating film 23a in a predetermined pattern (FIG. 3A). Then, the insulating film 23a is disposed on the base material 21 and the first electrically conductive pattern portion 22a as shown in FIG. 3B.

(Assembly structure of thermoelectric converter)

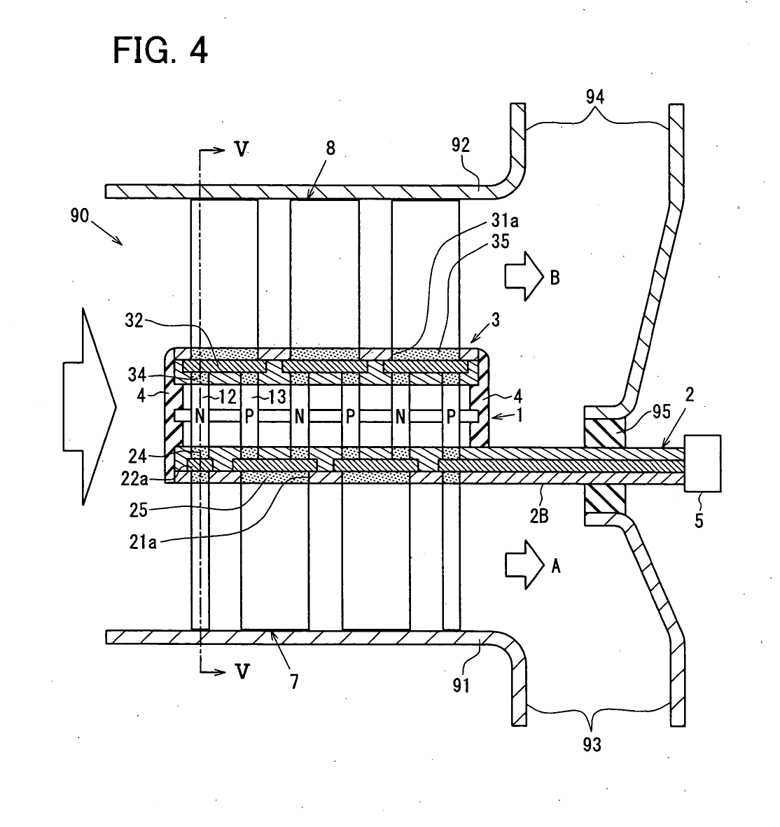

Now referring to FIGS. 4-7, the thermoelectric converter of FIGS. 1A-1C is shown assembled in a heat transfer duct 90. As will be explained in greater detail below, a heat transfer medium flows through the heat transfer duct 90, and the thermoelectric converter heats/cools the heat transfer medium. The heat transfer medium can be of any suitable type, such as air, liquid water, gaseous water, etc. Furthermore, as will be explained in greater detail below, the thermoelectric converter partitions the duct 90.

In the embodiment shown, the duct 90 includes a first case member 91 and a second case member 92. The first case member 91 includes a first exhaust opening 93, and the second case member 92 includes a second exhaust opening 94. As will be explained in greater detail, the heat transfer medium is heated and flows out of the duct 90 through the first exhaust opening 93, and the heat transfer medium is cooled and flows out of the duct 90 through the second exhaust opening 94. An exhaust fan (not shown) is disposed upstream of the thermoelectric converter for moving the heat transfer medium. As shown in FIG. 4, the extension member 2 is disposed downstream of the body 1 of the thermoelectric converter.

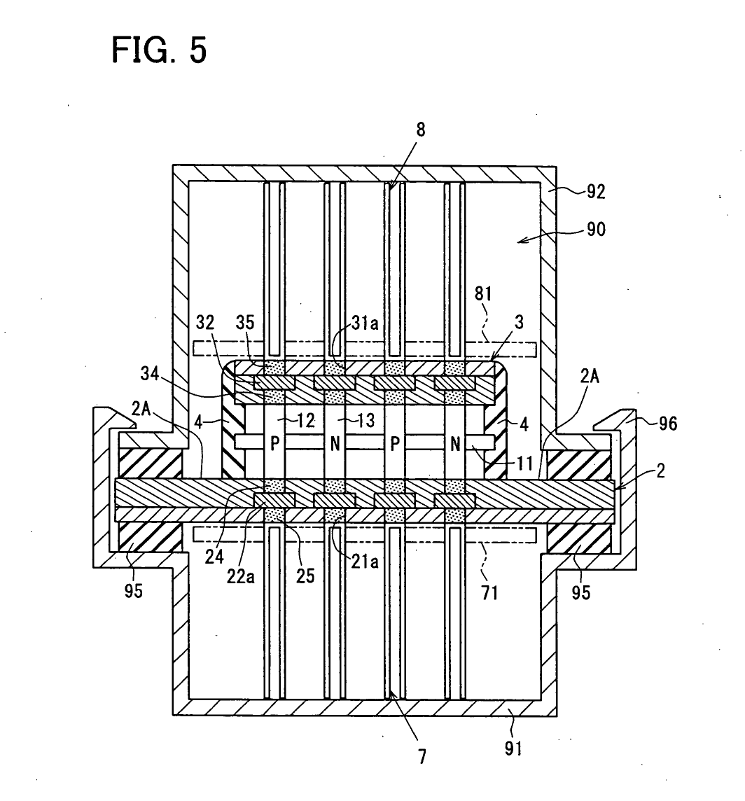

In the embodiment shown in FIG. 5, the first case member 91 includes an engaging member 96. For assembly, the first case member 91 is moved toward the second case member 92, and the engaging member 96 resiliently bends outward and clips over the second member 92. In another embodiment shown in FIG. 7, second case member 92 includes a pin with an enlarged head 92b, and the first case member 91 includes a corresponding engagement aperture 91a. For assembly, the first case member 91 moves toward the second case member 92 such that the head 92b resiliently deforms and moves through the aperture 91a, and the first and second case members 91, 92 are coupled.

As shown in FIG. 4, the first portion 2B of the extension member 2 is disposed between the first and second case members 91, 92. Also, as shown in FIG. 5, the second portions 2C of the extension member 2 are disposed between the first and second case members 91, 92. In the embodiment shown, a sealant 95 is disposed between the first case member 91 and the extension member 2 and between the second case member 92 and the extension member 2. Thus, the extension member 2 partitions the duct 90 and also supports the body 1 of the thermoelectric converter within the duct 90.

It will be appreciated that the extension member 2 partitions the duct 90 into a heating portion, A, in which the heat transfer medium is heated, and a cooling portion, B, in which the heat transfer medium is cooled. Further, the extension member 2 reduces heat transfer between both the heating and cooling portions A, B of the duct 90 due to the thermal insulating property of the base material 54 and the insulating film 56. Thus, the thermoelectric converter simplifies the design, manufacture, and assembly of the device because fewer components are necessary.

In the embodiment shown, the thermoelectric converter includes a plurality of heating electrode members 7 and a plurality of cooling electrode members 8. The electrode members 7, 8 are fins made of a high thermally conductive material (e.g., thin plate copper, etc.). Heating joining members 25 are disposed within corresponding openings 21a for thermally and structurally coupling the heating electrode members 7 and the first conductive pattern portion 22a. Likewise, cooling joining members 35 are disposed within corresponding openings 31a for thermally and structurally coupling the heating electrode members 8 and the second conductive pattern portion 32. In one embodiment, the heating and cooling joining members 25, 35 are each formed by soldering.

As such, heat transfer occurs between the first conductive pattern portion 22a and the heating electrode members 7, and the heat transfer medium is heated as the heat transfer medium flows past the heating electrode members 7. Likewise, heat transfer occurs between the second conductive pattern portion. 32 and the cooling electrode members 8, and the heat transfer medium is cooled as the heat transfer medium flows past the cooling electrode members 8. Therefore, losses in the heat transfer path can be reduced and efficiency can be increased.

It will be appreciated that the electrode members 7, 8 can be arranged in any suitable fashion within the duct 90. For instance, the electrode members 7, 8 can be arranged symmetrically within the duct 90 for more even heat transfer, and improved efficiency.

In the embodiment shown, the thermoelectric converter also includes a plurality of hold plates 71, 81 (shown in phantom lines). The hold plates 71, 81 are similar to the hold plate 11 described above. More specifically, the hold plates 71, 81 each include a plurality of apertures. The electrode members 7 extend through and are supported by the hold plate 71, and the electrode members 8 extend through and are supported by the hold plate 81. In one embodiment, the electrode members 7, 8 are soldered to the hold plates 71, 81, respectively. In one embodiment, the electrode members 7, 8 are coupled to the corresponding hold plate 71, 81 before being coupled to the body 1 of the thermoelectric converter for easier assembly.

Referring now to FIG. 6, a sectional view of one embodiment of the connector 5 is shown. A lead terminal 52 is formed within a housing 51 of the connector 5. The first portion 2B of the extension member 2 extends into the housing 51 and a lever 53 biases against the first portion 2B. As such, the power supply extension pattern portion 22b and the sensor signal extension pattern portion 22c are in electrical communication with the connector 5. Thus, the electrical connection is more reliable.

(Second embodiment)

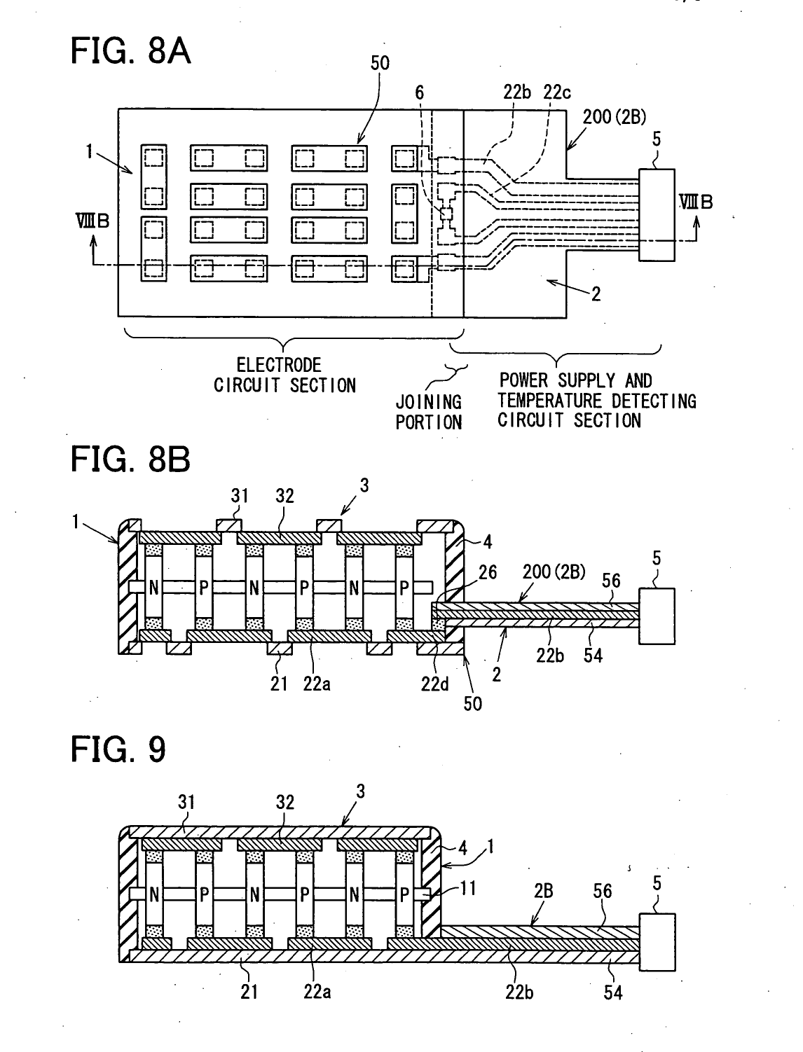

Referring now to FIGS. 8A and 8B, a second embodiment of the thermoelectric converter is shown. The second embodiment differs from the first embodiment shown in FIGS. 1A to 1C as follows. Namely, the extension member 2 includes a first portion 200. The first portion 200 is separate but coupled to at least one of the first and second substrates 50, 3. In the embodiment shown, the first portion 200 is coupled to the first substrate 50.

The first portion 200 includes a first insulating base material 54, an insulating film 56, a power supply extension pattern portion 22b, and a sensor signal extension pattern portion 22c similar to the embodiment of FIGS. 1A-1C. Furthermore, the first substrate 50 is a two-layer structure including the insulating base material 21 and the first electrically conductive pattern portion 22a. Likewise, the second substrate 3 includes the insulating base material 31 and the second electrically conductive pattern portion 32.

The electric power supply pattern portion 22b and the sensor signal pattern portion 22c formed in this electrode substrate 200 are collectively (simultaneously) soldered and joined to an electrode 22d of the first electrically conductive pattern portion 22a. As such, the electric power supply pattern portion 22b and the sensor signal pattern portion 22c are in electrical communication with the sensor signal pattern portion 22c.

As such, in the embodiment of FIGS. 8A and 8B, the electrical connections are reliable, and the design is structurally robust. Furthermore, because the first portion 200 of the extension member 2 is separate from the body 1, manufacturing can be facilitated. For instance, the materials of the first portion 200 and the first substrate 50 can be different.

(Third embodiment)

Referring now to FIG. 9, a third embodiment of the thermoelectric converter is illustrated. The third embodiment differs from the first embodiment shown in FIGS. 1A-1C as follows. Namely, the first substrate 50 is a two-layer structure that includes a first base material 21 and a first conductive pattern portion 22a. Likewise, the second substrate 3 is a two-layer structure that includes a second base material 31 and a second conductive pattern portion 32. The first portion 2B includes a first insulating base material 54, an insulating film 56, a power supply extension pattern portion 22b, and a sensor signal extension pattern portion 22c. Thus, the third embodiment of the thermoelectric converter can be easier to manufacture because it includes relatively few components.

(Fourth embodiment)

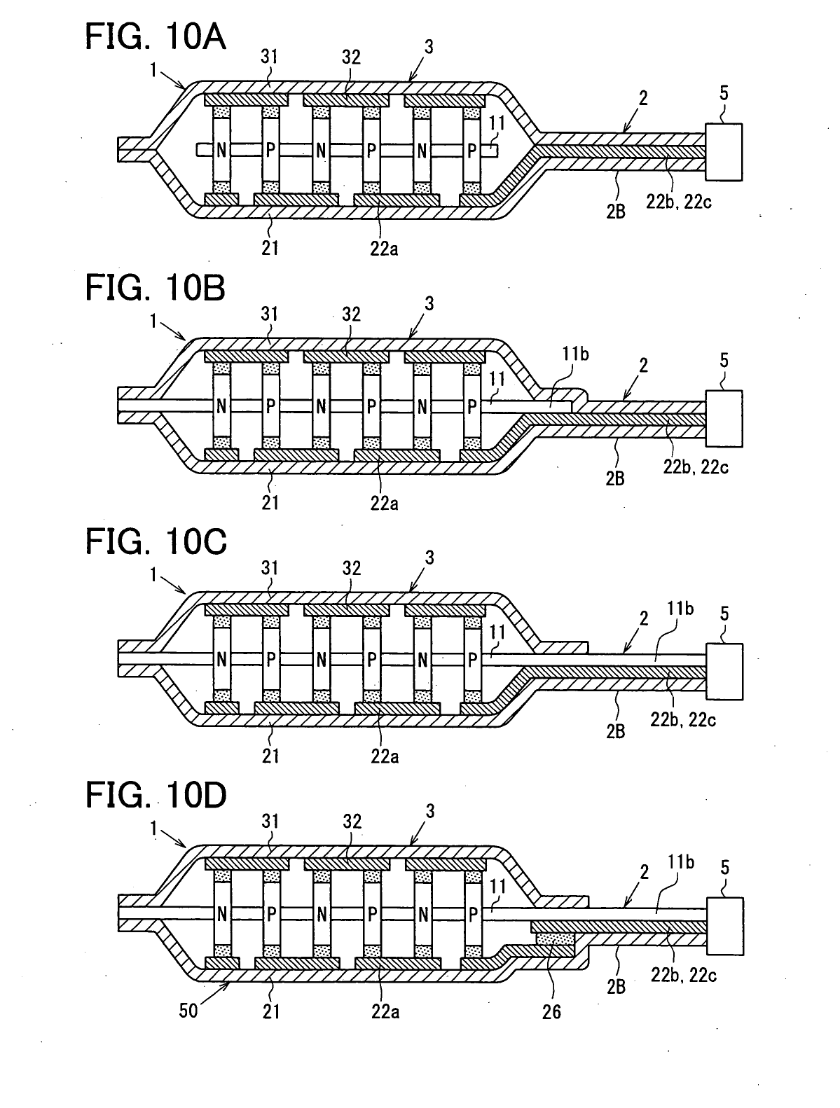

Referring now to FIGS. 10A-10D, a fourth embodiment is shown. Generally, in the fourth embodiment, the first insulating base material 21 of the first substrate 50 and the second insulating base material 31 extend away from the body 1 so as to at least partly define the first portion 2B of the extension member 2. The power supply extension pattern portion 22b and the sensor signal extension pattern portion 22c are interposed between the first and second insulating base materials 21, 31.

First, in the embodiment of FIG. 10A, the first and second substrates 50, 3 are molded in shape so as to encapsulate the thermoelectric elements 12, 13. Furthermore, the first and second insulating base materials 21, 31 extend away from the body 1 so as to cover respective sides of the power supply extension pattern portion 22b and the sensor signal extension pattern portion 22c.

Thus, because there are fewer necessary components, manufacture of the thermoelectric converter is facilitated, and costs can be reduced. Furthermore, the operating life and reliability of the thermoelectric converter can be improved.

The embodiment of FIGS. 10B-10D are substantially similar to that of FIG. 10A, except that the hold plate 11 described above includes an extending portion 11b that extends over the first portion 2B. As such, the power supply extension pattern portion 22b and the sensor signal extension pattern portion 22c are interposed between the first insulating base material 21 and the extending portion 11b of the hold plate 11. In the embodiment of FIGS. 10B, the extending portion 11b extends only partially over the first portion 2B. In the embodiments of FIGS. 10C and 10D, the extending portion 11b extends over the entire first portion 2B. Also, both ends of the hold plate 11 are interposed between the first and second insulating base materials 21, 31 for support of the hold plate 11. As such, the thermoelectric converter includes fewer components for facilitating manufacture, lowering costs, etc.

In the embodiment of FIG. 10D, the power supply extension pattern portion 22b and the sensor signal extension pattern portion 22c are separate but electrically coupled to the first conductive pattern portion 22a via the connecting member 26. The extending portion 11b of the hold plate 11 covers one side of the power supply extension pattern portion 22b and the sensor signal extension pattern portion 22c. The first insulating base material 21 covers the opposite side of the power supply extension pattern portion 22b and the sensor signal extension pattern portion 22c. As such, the thermoelectric converter includes fewer components for facilitating manufacture, lowering costs, etc.

(Other embodiments)

In each of the embodiments of FIGS. 9 and 10A-10D, the first and second insulating base materials 21, 31 are continuous. As such, the electrode members 7, 8 (FIGS. 4 and 5) are coupled to the first and second insulating base materials 21, 31, respectively. As such, the thermoelectric elements 12, 13 are well protected from moisture, etc. within the body 1.

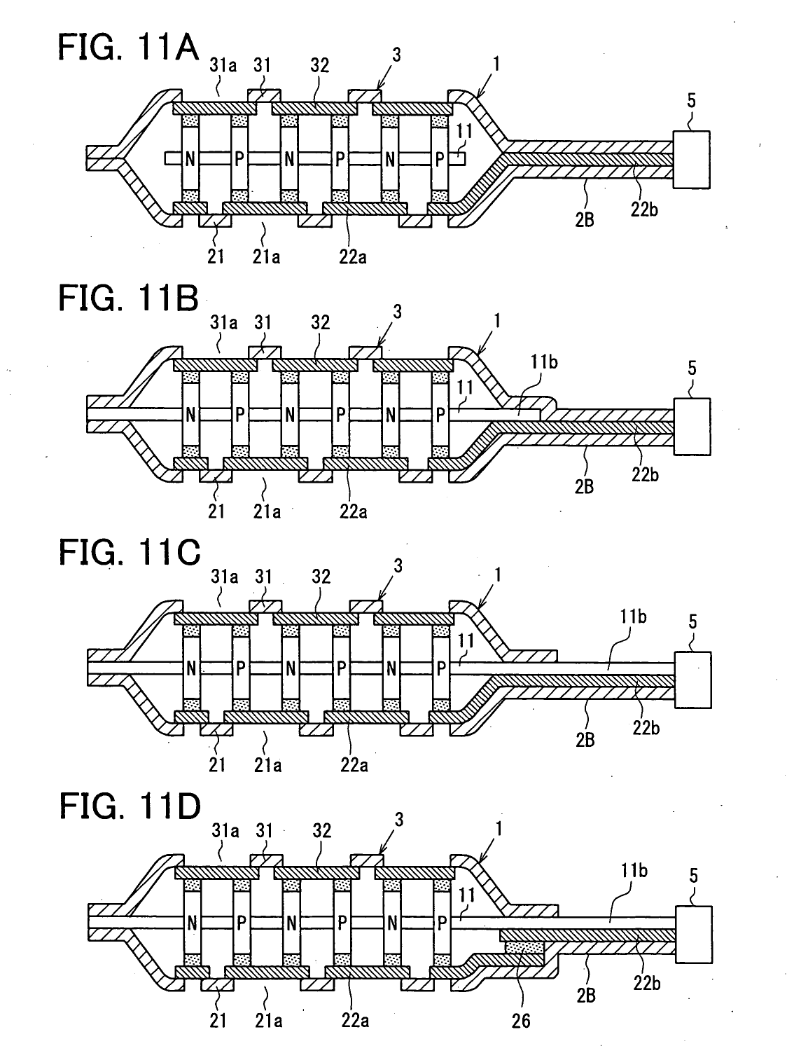

The embodiments of FIGS. 11A to 11D correspond to the embodiments of FIGS. 10A to 10D. However, the first and second insulating base materials 21, 31 include the opening portions 21a, 31a described above for joining the first and second electrode members 7, 8, to the first and second conductive portions 22a, 32, respectively. In accordance with this construction, the opening portions 21a, 31a can be hermetically sealed in joining portions of the first and second insulating base materials 21, 31 and the electrode portions 22a, 32a so that the invasion of a water droplet, etc. into the internal thermoelectric element assembly body 1 can be prevented.

Further, as another modified example, an electric power supply circuit and a temperature detecting circuit may be also allocated to both the first and second substrates 50, 3. Further, the number of parts can be reduced if the connector 5 is integrally formed in the case members 91, 92.

A number of embodiments of the invention have been described. Nevertheless, it will be understood that various modifications may be made without departing from the spirit and scope of the invention such as executing all or portions of the adaptation method in a base station. Accordingly, other embodiments are within the scope of the following claims.

What is claimed is:

1. A thermoelectric converter comprising:
a body comprising:
a plurality of dissimilar thermoelectric elements in an array;
a first substrate with a first electrically conductive pattern portion that is electrically connected to the plurality of dissimilar thermoelectric elements; and
a second substrate with a second electrically conductive pattern portion that is electrically connected to the plurality of dissimilar thermoelectric elements; and
an extension member with an extension pattern portion that is electrically connected to at least one of the first and second electrically conductive pattern portions, the extension member extending away from the body.

2. The thermoelectric converter according to claim 1, wherein the plurality of dissimilar thermoelectric elements include at least one P-type semiconductor and at least one N-type semiconductor.

3. The thermoelectric converter according to claim 1, wherein the extension member is at least partially planar in shape.

4. The thermoelectric converter according to claim 1, wherein the extension member is integrally connected to at least one of the first and second substrates, and wherein the extension pattern portion is integrally connected to at least one of the first and second electrically conductive pattern portions.

5. The thermoelectric converter according to claim 1, wherein the extension member is separate but coupled to at least one of the first and second substrates, and wherein the extension pattern portion is separate but electrically coupled to at least one of the first and second electrically conductive pattern portions.

6. The thermoelectric converter according to claim 1, further comprising an insulating member that covers at least a portion of the extension pattern portion.

7. The thermoelectric converter according to claim 1, further comprising a holding member with a plurality of apertures, wherein the plurality of dissimilar thermoelectric elements extend through corresponding ones of the plurality of apertures for support.

8. The thermoelectric converter according to claim 7, wherein the holding member extends over the extension member and covers at least a portion of the extension pattern portion.

9. The thermoelectric converter according to claim 4, wherein the first substrate includes a first insulating material, wherein the second substrate includes a second insulating material, and wherein the first insulating material and the second insulating material extend away from the array so as to define the extension member, and wherein the extension pattern portion is interposed between the first insulating material and the second insulating material.

10. A thermoelectric converter comprising:
a body comprising:
a plurality of dissimilar thermoelectric elements in an array;
a first substrate with a first electrically conductive pattern portion, the first substrate disposed on a first side of the array, the first electrically conductive pattern portion electrically connected to the plurality of dissimilar thermoelectric elements, and the first electrically conductive pattern portion including a first electrode portion;
a second substrate with a second electrically conductive pattern portion, the second substrate disposed on a second side of the array, the second electrically conductive pattern portion electrically connected to the plurality of dissimilar thermoelectric elements, and the second electrically conductive pattern portion including a second electrode portion;
at least one cooling electrode member thermally coupled to the first electrode portion for heat transfer therewith; and
at least one heating electrode member thermally coupled to the second electrode portion for heat transfer therewith; and
an extension member with an extension pattern portion that is electrically connected to at least one of the first and second electrically conductive pattern portions, the extension member extending away from the body.

11. The thermoelectric converter according to claim 10, further comprising at least one cooling joining member for thermally coupling the at least one cooling electrode member to the first electrode portion, and at least one heating joining member for thermally coupling the at least one heating electrode member to the second electrode portion.

12. The thermoelectric converter according to claim 10, wherein the first substrate includes at least one opening that exposes the first electrode portion for thermally coupling the at least one cooling electrode member to the first electrode portion, and wherein the second substrate includes at least one opening that exposes the second electrode portion for thermally coupling the at least one heating electrode member to the second electrode portion.

13. A heat transfer device for a duct through which a heat transfer medium flows, the heat transfer device comprising:
a body comprising:
a plurality of dissimilar thermoelectric elements in an array;
a first substrate with a first electrically conductive pattern portion that is electrically connected to the plurality of dissimilar thermoelectric elements; and
a second substrate with a second electrically conductive pattern portion that is electrically connected to the plurality of dissimilar thermoelectric elements; and
an extension member with an extension pattern portion that is electrically connected to at least one of the first and second electrically conductive pattern portions, the extension member extending away from the body so as to partition the duct into a cooling portion, in which the heat transfer medium is cooled, and a heating duct, in which the heat transfer medium is heated.

14. The heat transfer device according to claim 13, wherein the duct is defined by a first case member and a second case member, and wherein the extension member is disposed between the first case member and the second case member to thereby partition the duct and to thereby support the body in the duct.

15. The heat transfer device according to claim 13, wherein the extension member is disposed downstream of the body.

16. The heat transfer device according to claim 13, further comprising:
at least one cooling electrode member thermally coupled to the first electrode portion for heat transfer therewith, wherein the at least one cooling electrode member is disposed within the cooling portion of the duct; and
at least one heating electrode member thermally coupled to the second electrode portion for heat transfer therewith, wherein the at least one heating electrode member is disposed within the heating portion of the duct.
